(19) United States
(12) Patent Application Publication
(10) Pub. No.: US 2022/0199882 A1
(43) Pub. Date: Jun. 23, 2022

(54) LIGHT EMITTING DIODE CHIP-SCALE PACKAGE AND METHOD FOR MANUFACTURING SAME

(71) Applicant: Lightizer Co., Ltd., Yongin-si, Gyeonggi-do (KR)

(72) Inventors: Jae Sik MIN, Yongin-si, Gyeonggi-do (KR); Jae Yeop LEE, Yongin-si, Gyeonggi-do (KR); Jae Suk PARK, Yongin-si, Gyeonggi-do (KR); Byoung Gu CHO, Yongin-si, Gyeonggi-do (KR)

(21) Appl. No.: 17/600,403

(22) PCT Filed: Mar. 26, 2020
(86) PCT No.: PCT/KR2020/004091

§ 371 Date: Sep. 30, 2021

(30) Foreign Application Priority Data
Apr. 1, 2019 (KR) 10-2019-0037650

(51) Int. Cl. H01L 33/64; H01L 33/60

(52) U.S. Cl. CPC H01L 33/647; H01L 33/60; H01L 33/56; H01L 2933/0075; H01L 2933/0058

(57) ABSTRACT

The present invention provides a LED chip scale package, comprising: a light emitting diode chip having a pad electrically connected to an external object on one side thereof, a phosphor silicon film surrounding the light emitting diode chip so that a bonding surface of the pad is exposed to an outside, and a metal layer connected to the bonding surface and expanding a surface area of the pad, and a method for manufacturing the same.

### TECHNICAL FIELD

The present invention relates to a chip scale package in which a pad size of a light emitting diode chip is increased, and a method for manufacturing the same.

### BACKGROUND TECHNOLOGY

Light Emitting Diodes (LEDs) are attracting attention as they have a longer lifecycle, less power consumption, excellent brightness, and are not harmful to a human body compared to incandescent lamps. In particular, as it becomes possible to produce a light emitting diode emitting white light through a chip scale package, the light emitting diode is in the spotlight.

In general, a light emitting diode chip emitting blue light is used in such a light emitting diode chip scale package. In order to convert a blue light of the light emitting diode chip into any one of white light, red light, and green light, a silicon phosphor film 20 is disposed on a surface of the light emitting diode chip 10 as shown in FIG. 1. More specifically, the light emitting diode chip 10 for emitting blue light is wrapped by a silicon phosphor film 20, and, the silicon phosphor film 20 converts the color of a light which is emitted from the LED chip 10 to outside.

However, in this conventional light emitting diode chip scale package 30, a pad 40 of the light emitting diode chip 10 which is electrically connected to an external object is very small. Therefore, in the process of electrically connecting a substrate and the light emitting diode chip 10 using a surface mounting technology, there is a problem in that defects such as open/short circuit occurs. This problem becomes more highlighted as a critical problem as the size of the light emitting diode chip 10 decreases. More specifically, in the case of the conventional light emitting diode chip 10, as shown in FIG. 1, since the width length R1 of the pad 40 is short, the area that can substantially be connected to the substrate is small. Therefore, according to the conventional light emitting diode chip 10, there was a problem that electrical connection to a circuit formed on the substrate cannot be done securely. In addition, the conventional light emitting diode chip 10, even if the pad 40 is securely connected to the substrate, still had a problem that a short circuit easily occurs because a gap L1 between the pads 40 is too narrow.

Accordingly, there is a need for a new light emitting diode chip scale package capable of solving the problems of the conventional light emitting diode chip scale package, and a method for manufacturing the same.

### PRIOR ART LITERATURE

### Patent Document

(Patent Document 1) Korean Laid-Open Patent Publication No. 2019-0017439 (Title: Light emitting device package and light emitting device package module, published on 2019 Feb. 20)

### DETAILED DESCRIPTION OF THE INVENTION

### Technical Problems

The present invention has been made in order to solve the above problem, and an object of the present invention is to provide a light emitting diode chip scale package and a method for manufacturing the same, by expanding an area of a pad formed on the light emitting diode chip which is electrically connected to a substrate, thereby solving electrical problems occurring during the connection process of the light emitting diode chip scale package to the substrate.

### Technical Solution

A light emitting diode chip scale package according to the present invention for achieving the object as described above, comprises: a light emitting diode chip 100 on one surface of which a pad 110 electrically connected to an external object is formed; a phosphor silicon film 200 surrounding the light emitting diode chip 100 so that a bonding surface 111 of the pad 110 is exposed to outside; and a metal layer 300 connected to the bonding surface 111 and expanding a surface area of the pad 110.

In addition, the pad 110 includes a pair of pad units 110A spaced apart from each other, and the metal layer 300 includes a pair of metal layer units 300A connected to each of the pad units 110A. A separation distance L2 between the metal layer units 300A is larger than or equal to a separation distance L1 between the pad units 110A.

A method for manufacturing a light emitting diode chip scale package according to the present invention for achieving the above object, comprises: a package forming step S100 of wrapping a light emitting diode chip 100 with a phosphor silicon film 200 and exposing a bonding surface 111 of a pad 110 to an outside; and a pad expanding step S200 of expanding the pad 110 by bonding a metal layer 300 to the bonding surface 111.

Further, the package forming step (S100) comprises: a frame coupling step S110 of coupling vertical frames 500 to a substrate 400 to form a hole 600; a diode arranging step S120 of arranging the light emitting diode chip 100 on the hole 600; a liquid injection step S130 of injecting a mixed solution 200A on the hole 600; a film forming step S140 of processing the mixed solution 200A injected on the hole 300 to convert the mixed solution 200A into a phosphor silicone film 200; and a substrate removing step S150 of removing the substrate 400 to form a package plate 700 in which the pad 110 is exposed to an outside.

The mixed solution 200A is a mixture of a phosphor and silicon.

The pad expanding step S200 comprises: a shadow mask combining step S210 of combining a shadow mask 800 to one surface of the vertical frame 700 and one surface of the phosphor silicon film 200 positioned in the groove 112 formed between the pads which are exposed by removing the substrate 400 at the substrate removing step S150.

The pad expanding step S200 comprises: a metal deposition step S220 of depositing a metal on one surface of the package plate 700 to which the pad 110 is exposed.

In the metal deposition step S220, the deposition of a metal is performed by any one of a vacuum deposition method (E-beam) and a sputtering method.

The pad expanding step S200 comprises: a shadow mask removing step S230 of removing the shadow mask 800 combined to the package plate 700; and a frame removing step S240 of removing the vertical frame 500.

### Effects of the Invention

The light emitting diode chip scale package manufactured using the method of manufacturing the light emitting diode chip scale package in accordance with the present invention can expand an area of a pad formed on the light emitting diode by using a metal layer, and thus since the size of the pad can be small, thereby minimizing electrical defects.

Further, since a metal layer is bonded on the lower surface of the light emitting diode chip scale package, surface area of the LED chip scale package is expanded, a heat arising from the LED chip can be dissipated more easily.

Further, in the case of a light emitted by a lower surface of the LED chip, because the light inputted to the metal layer is reflected to an upper or side surface, the present invention is beneficial that light efficiency of the LED can be maximized.

### BRIEF DESCRIPTION OF DRAWINGS

FIG. 1 is a schematic diagram illustrating a conventional light emitting diode chip scale package.

FIG. 2 is a perspective view showing a light emitting diode chip scale package according to the present invention.

FIG. 3 is a cross-sectional view showing a light emitting diode chip scale package according to the present invention.

FIG. 4 is a flowchart illustrating a method for manufacturing a light emitting diode chip scale package according to the present invention.

FIGS. 5 to 8 are process diagrams illustrating a method for manufacturing a light emitting diode chip scale package according to the present invention.

### EMBODIMENTS FOR IMPLEMENTING THE PRESENT INVENTION

Advantages and features of embodiments of the present invention, and methods of achieving them, will become apparent with reference to the embodiments described below in detail in conjunction with the accompanying drawings. However, the present invention cannot be construed as being limited to the embodiments set forth herein, and may be embodied in many different forms as well. And, the present embodiments are only for fully disclosing the present invention. In addition, the present embodiments are provided to completely disclose the scope of the present invention to those of ordinary skill in the art to which the present invention pertains. The invention is only defined by the scope of the claims. Like reference numerals refer to like elements throughout.

In describing the embodiments of the present invention, if it is determined that a detailed description of a well-known function or configuration may unnecessarily obscure the gist of the present invention, the detailed description thereof will be omitted. And, the terms to be described later are terms defined in consideration of the functions in the embodiment of the present invention, which may vary according to the intention or custom of the user or operator. Therefore, the definition should be made based on the content throughout this specification.

Hereinafter, a light emitting diode chip scale package 1000 according to the present invention will be described with reference to the accompanying drawings.

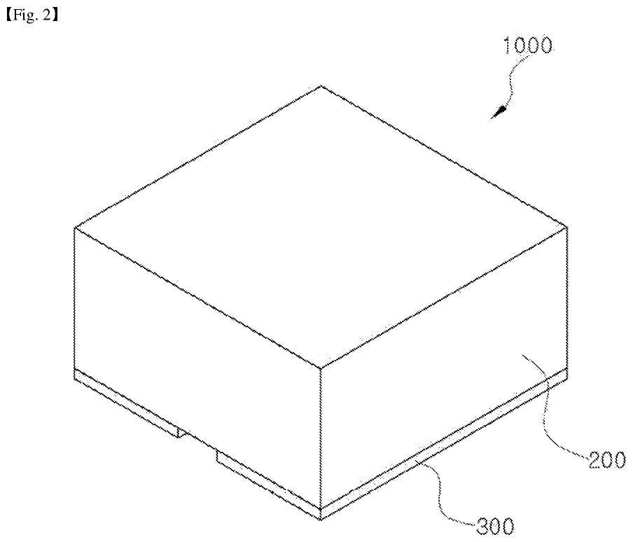

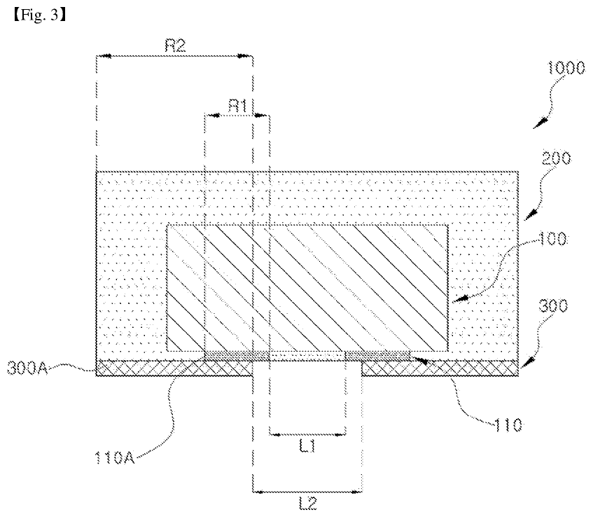

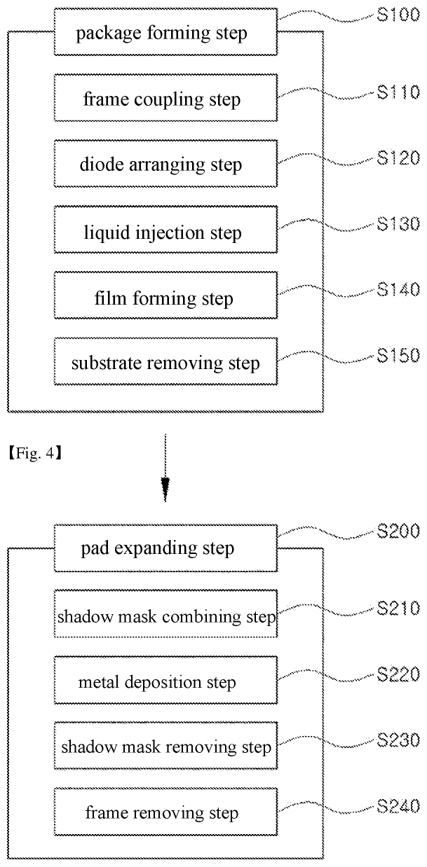

FIG. 2 is a perspective view showing the light emitting diode chip scale package 1000 according to the present invention, and FIG. 3 is a cross-sectional view showing the light emitting diode chip scale package 1000 according to the present invention.

With reference to FIGS. 2 and 3, the LED chip scale package 1000 comprises, a light emitting diode chip 100 having a pad 110 electrically connected to an external object on one surface thereof; a phosphor silicon film 200 surrounding the light emitting diode chip 100 so that a bonding surface 111 of the pad 110 is exposed to an outside; and a metal layer 300 connected to the bonding surface 111 and expanding a surface area of the pad 110.

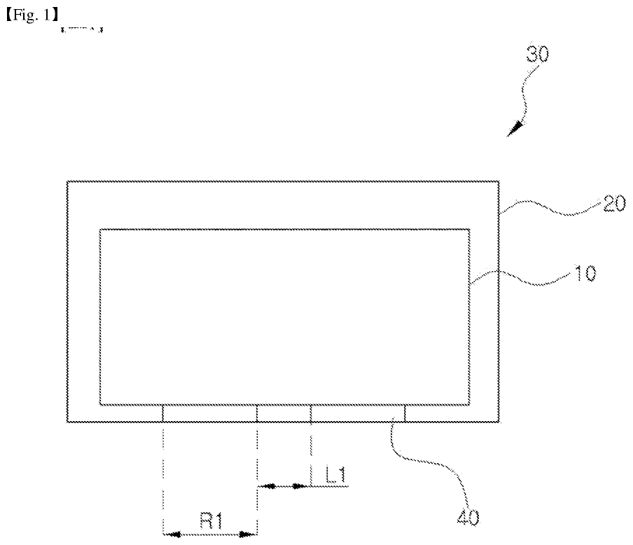

More specifically, as described with reference to FIG. 1, in case of a light emitting diode chip, a structure surrounding an outer circumferential surface of the LED chip with a phosphor silicon film is necessary in order to emit white light to the outside. In this case, however, since edge portion of the pad which is formed on a lower surface of the LED chip is also wrapped by a phosphor silicon film, a part to be connected to the substrate is restricted to the lower surface of the pad, a problem arises that electrical connection is not done properly during the mounting process of the LED chip. In addition, the gap between the pads formed on the bottom surface of the light emitting diode chip is too narrow, so that the conductors connected to the respective pads become too closer, and therefore, a short circuit problem also occurs. Therefore, in the present invention, a surface area of the pad 110 to which the substrate is connected can be widen through the metal layer 300, the LED chip 100 is made so that good electrical connection with an external circuit is achieved. In addition, according to the present invention, a gap between wires which are connected to the pad 110 can be widened, possibility of short circuit problem can also be minimized.

In this case, the pad 110 may be comprised of a pair of pad units 110A. The metal layer 300 may include a pair of metal layer units 300A connected to each of the pad units 110A. In order to expand the surface area of the pad unit 110A which is exposed to the outside, the width direction length R2 of the metal unit 300A is preferably to be formed longer than the width direction length R1 of the pad unit 110A. It is preferable that the separation distance L2 of the metal layer units 300A be larger than the separation distance L1 of the pad units 110A in order to increase the distance between the conductive wires which are connected to the pads.

In other words, by making the width direction length R2 of the metal layer unit 300A longer than the width direction length R1 of the pad unit 110A, the metal layer unit 300A can be electrically connected to the substrate more smoothly. By making the separation distance L2 between the metal layer units 300A larger than the separation distance L1 between the pad units 110, when a current flow through the metal layer unit 300A, the current flowing through the metal layer unit 300A is prevented from flowing out of the original flow route due to unnecessary contact thereby generating short circuit.

In addition, in the light emitting diode chip scale package 1000 according to the present invention, as described above, the metal layer 300 electrically connected to the pad 110 is formed on the lower surface, so that the problem of electrical failure can be solved as well as the metal layer 300 acts as a heat sink and a reflector, thereby improving a heat dissipation efficiency and a light efficiency. More specifically, when the metal layer 300 is formed on a lower surface, a surface area of the metal layer 300 is larger than the sum of a bonding surface 111 of the pad 110 on which the metal layer 300 is bonded and a surface area of the phosphor silicon film 200, and the heat dissipation efficiency is increased. In addition, among the light emitted from the light emitting diode chip 100, the light emitted to the lower surface, which had been scattered or absorbed on the surface of the substrate to which the light emitting diode chip scale package is bonded and thereby being wasted, is reflected by the metal layer 300 to the upper or side surface and the light efficiency also increases.

Hereinafter, with reference to the drawings, a method of manufacturing the light emitting diode chip scale package 1000 described above will be described.

FIG. 4 is a flowchart illustrating a method for manufacturing a light emitting diode chip scale package.

Referring to FIG. 4, a method of manufacturing the light emitting diode chip scale package, comprises: a package forming step S100 of wrapping a light emitting diode chip 100 with a phosphor silicon film 200 and exposing a bonding surface 111 of a pad 110 to an outside; and a pad expanding step S200 of expanding the pad 110 by bonding a metal layer 300 to the bonding surface 111.

The package forming step S100 comprises: a frame coupling step S110 of coupling vertical frames 500 to a substrate 400 to form a hole 600; a diode arranging step S120 of arranging the light emitting diode chip 100 on the hole 600; a liquid injection step S130 of injecting a mixed solution 200A on the hole 600; a film forming step S140 of processing the mixed solution 200A injected on the hole 300 to convert the mixed solution 200A into a phosphor silicone film 200; and a substrate removing step S150 of removing the substrate 400 to form a package plate 700 in which the pad 110 is exposed to an outside.

The pad expanding step S200 comprises: a shadow mask combining step S210 of combining a shadow mask 800 to restrict a position to which a metal is deposited; a metal deposition step S220 of depositing a metal on one surface of the package plate 700 to which the shadow mask 800 is combined; a shadow mask removing step S230 of removing the shadow mask 800 after the deposition of the metal; and a frame removing step S240 of removing the vertical frame 500.

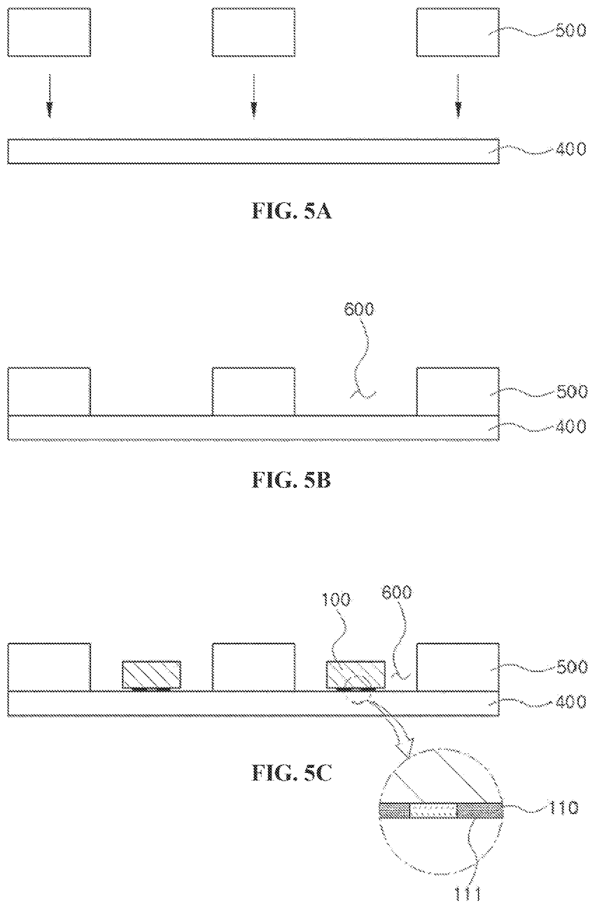

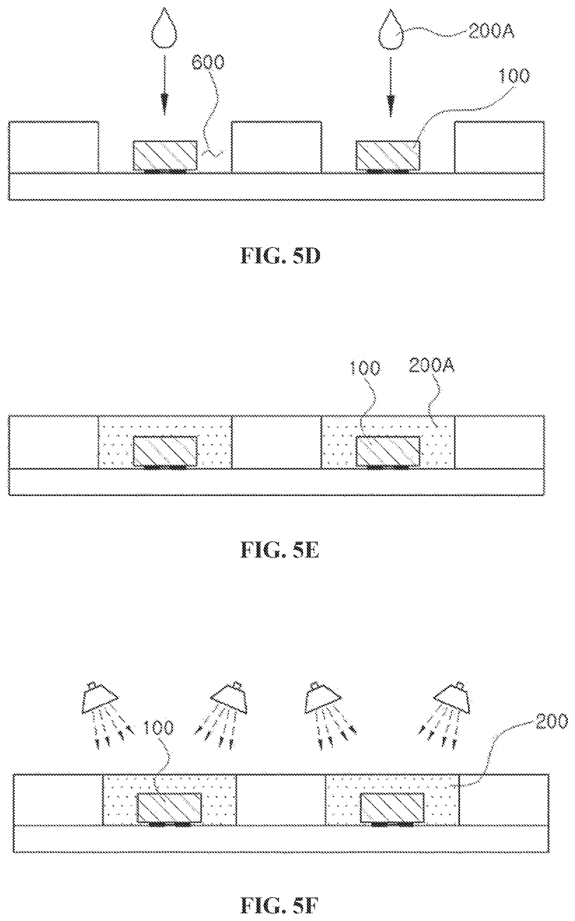

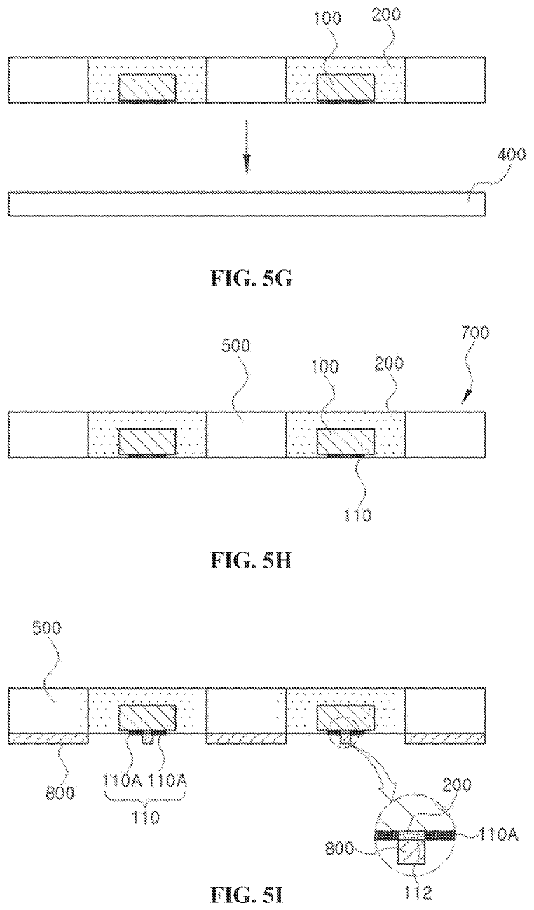

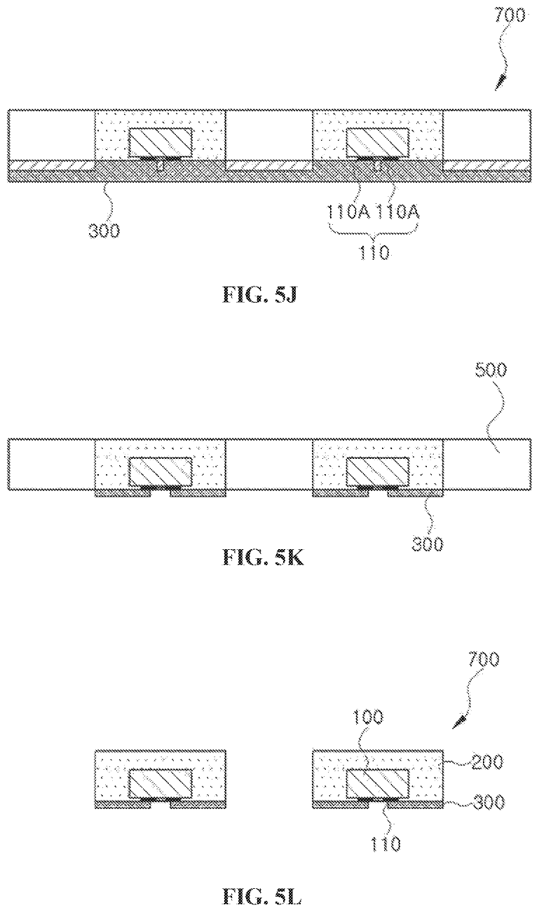

Hereinafter, the method is described more specifically with reference to the process diagrams of FIGS. 5 to 8.

In the frame coupling step S110, as illustrated in FIG. 5 (a), the vertical frame 500 is seated on the substrate 400. As shown in FIG. 5 (b), the substrate 400 and the vertical frame 500 are coupled, thereby to form a hole 600 between the vertical frames 500.

Then, in the diode arranging step S120, as illustrated in FIG. 5 (c), the light emitting diode chip 100 is disposed at a center of each of the holes 600, thereby making the bonding surface 111 of the pad 110 to be brought into contact with the substrate 400.

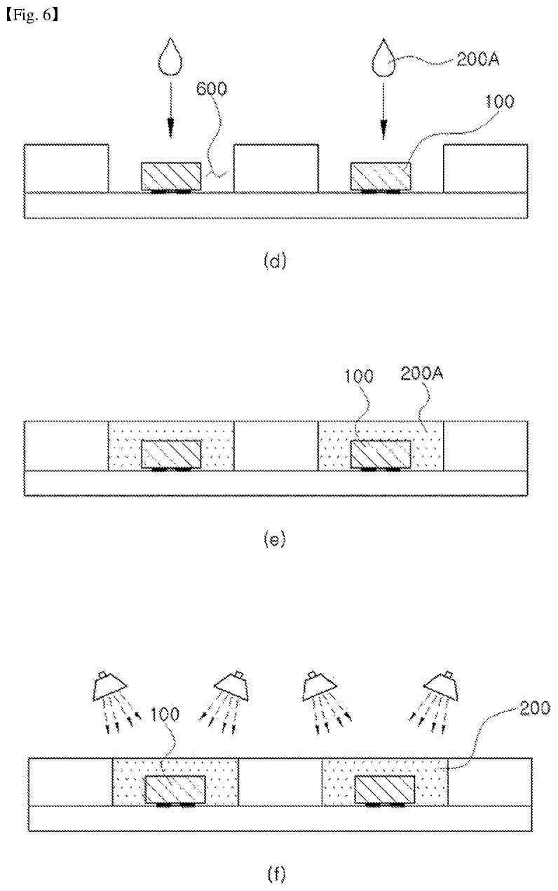

Then, in the fluid injection step S130, as shown in FIG. 6 (d), a mixture solution 200A made by mixing at least one phosphor and silicon is injected in each of the holes 600. As shown in FIG. 6 (e), the light emitting diode chip 100 positioned in the hole 600 is wrapped around by the injected mixed solution 200A.

Then, in the film forming step S140, by applying heat or light to the liquid mixed solution 200A, the mixed solution 200A is solidified and converted into a phosphor silicon film 200.

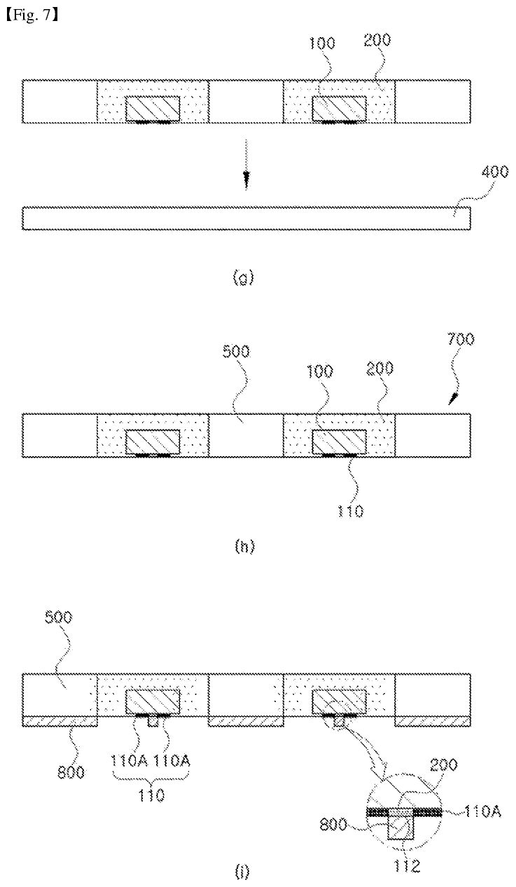

Then, in the substrate removing step S150, as shown in FIG. 7 (g), the substrate 400 is removed. As shown in FIG. 7 (h), a package plate 700 where the pad 110 is exposed to the outside is formed.

Then, in the shadow mask combining step S210, as shown in FIG. 7 (i), a shadow mask 800 is combined to one surface of the vertical frame 700 and one surface of the phosphor silicon film 200 positioned in the groove 112 formed between the pads which are exposed by removing the substrate 400.

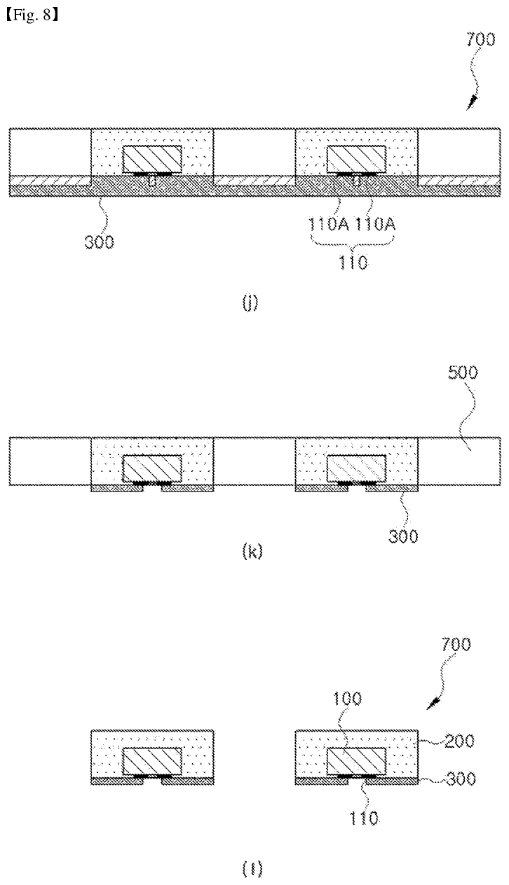

Then, in the metal deposition step S220, as shown in FIG. 8 (j), when the metal layer 300 is formed by depositing a metal on one surface of the package plate 700, the metal layer 300 is formed in a designated region thereby being connected to the pad 110.

Then, in the shadow mask removing step S230, as illustrated in FIG. 8 (k), the shadow mask 800 located outside the designated region is removed so that the metal layer 300 is located only in a specific region where the shadow mask was not located.

Then, in the frame removing step S240, as shown in FIG. 8 (l), the vertical frame 500 is removed to complete the manufacture of the light emitting diode chip scale package 1000 according to the present invention.

In addition, since the metal layer should be formed very thin during the metal deposition conducted during the metal deposition step S220, it can preferably be used one of methods of a so-called Vacuum Evaporation (Vacuum Evaporation Coating, Vacuum Deposition) method in which evaporating molecules are attached to one surface of a low-temperature package plate thereby forming the metal layer 300 or a so-called sputtering method in which ionized gas atoms collide with one surface of a package plate thereby forming the metal layer 300 on a substrate. The metal layer 300 may be Cr/Au or a Cr/AuSu alloy.

The present invention is not limited to the above-described embodiments, and any person having ordinary skill in the art may perform various modifications without departing from the gist of the present invention claimed in the claims.

### EXPLANATION OF REFERENCE NOS

100: light emitting diode chip
110: pad
110A: pad unit
111: bonding surface
200: phosphor silicone film
200A: mixed solution
300: metal layer
300A: metal layer unit
400: substrate
500: vertical frame
600: hole
700: package plate
800: shadow mask
S100: package forming step
S110: frame combining step
S120: diode arranging step
S130: liquid injection step
S140: film forming step
S150: substrate removing step
S200: pad expansion step
S210: shadow mask combining step
S220: metal deposition step
S230: shadow mask removing step
S240: frame removing step

1. A LED chip scale package, comprising:
a light emitting diode chip having a pad electrically connected to an external object on one surface thereof;
a phosphor silicon film surrounding the light emitting diode chip so that a bonding surface of the pad is exposed to an outside; and
a metal layer connected to the bonding surface and expanding a surface area of the pad.

2. The LED chip scale package of claim 1, wherein
the pad includes a pair of pad units spaced apart from each other,
the metal layer includes a pair of metal layer units connected to each of the pad units, and
a separation distance between the metal layer units is larger than or equal to a separation distance between the pad units.

3. A method for manufacturing a light emitting diode chip scale package of claim 1, comprising:
a package forming step of wrapping a light emitting diode chip with a phosphor silicon film and exposing a bonding surface of a pad to an outside; and
a pad expanding step of expanding the pad by bonding a metal layer to the bonding surface.

4. The method of claim 3, wherein
the package forming step comprises:
a frame coupling step of coupling vertical frames to a substrate to form a hole;
a diode arranging step of arranging the light emitting diode chip on the hole;
a liquid injection step of injecting a mixed solution on the hole;
a film forming step of processing the mixed solution injected on the hole to convert the mixed solution into a phosphor silicone film; and
a substrate removing step of removing the substrate to form a package plate in which the pad is exposed to an outside.

5. The method of claim 4, wherein the mixed solution is a mixture of a phosphor and silicon.

6. The method of claim 4, wherein
the pad expanding step comprises:
a shadow mask combining step of combining a shadow mask to one surface of the vertical frame and one surface of the phosphor silicon film positioned in the groove formed between the pads which are exposed by removing the substrate at the substrate removing step.

7. The method of claim 6, wherein
the pad expanding step comprises:
a metal deposition step of depositing a metal on one surface of the package plate to which the pad is exposed.

8. The method of claim 7, wherein
in the metal deposition step,
the deposition of a metal is performed by any one of a vacuum evaporation method (E-beam) and a sputtering method.

9. The method of claim 7, wherein
the pad expanding step comprises:
a shadow mask removing step of removing the shadow mask combined to the package plate; and
a frame removing step of removing the vertical frame.
